(19) United States
(12) Patent Application Publication
(10) Pub. No.: US 2015/0036272 A1
(43) Pub. Date: Feb. 5, 2015

(54) ELECTRONIC DEVICE AND SUBSTRATE UNIT

(71) Applicant: FUJITSU LIMITED, Kawasaki-shi (JP)

(72) Inventors: Masanori Tachibana, Yokohama (JP); Yukihiro Hirano, Fucyu (JP); Misao Umematsu, Kawasaki (JP)

(21) Appl. No.: 14/324,393

(22) Filed: Jul. 7, 2014

(30) Foreign Application Priority Data
Aug. 1, 2013 (JP) 2013-160635

(51) Int. Cl. G06F 1/18; H05K 1/11

(52) U.S. Cl. CPC G06F 1/189; G06F 1/181; H05K 1/11
USPC 361/679.4; 174/261

(57) ABSTRACT

An electronic device includes: substrate unit including a signal terminal provided over a first edge of a substrate body, and a power terminal provided over a second edge that is different from the first edge; and a case including an insertion unit into which the substrate unit is inserted from the first edge, a signal connection member to which the signal terminal is coupled when the substrate unit is inserted into the insertion unit, and a power connection member to which the power terminal is coupled when the substrate unit is inserted into the insertion unit.

### CROSS-REFERENCE TO RELATED APPLICATION

This application is based upon and claims the benefit of priority of the prior Japanese Patent Application No. 2013-160635 filed on Aug. 1, 2013, the entire contents of which are incorporated herein by reference.

### FIELD

The embodiments discussed herein are related to an electronic device and a substrate unit.

### BACKGROUND

There is a feeding bar assembly configured to supply power from a feeding bar assembly of a backplane through a socket connector of a package board to a package board, and to transmit signal data to the package board via a package connector.

In order to suppress the generation of noise or heat, a substrate unit on which electronic parts are mounted at high density requires that signal wiring not be laid at high density.

The following is a reference document.

[Document 1] Japanese Laid-Open Patent Publication No. H8-115773

### SUMMARY

According to an aspect of the invention, an electronic device includes: substrate unit including a signal terminal provided over a first edge of a substrate body, and a power terminal provided over a second edge that is different from the first edge; and a case including an insertion unit into which the substrate unit is inserted from the first edge, a signal connection member to which the signal terminal is coupled when the substrate unit is inserted into the insertion unit, and a power connection member to which the power terminal is coupled when the substrate unit is inserted into the insertion unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view illustrating an electronic device of a first exemplary embodiment;

FIG. 2 is a plan view illustrating a portion of the electronic device of the first exemplary embodiment;

FIG. 3 is a perspective view illustrating a portion of the electronic device of the first exemplary embodiment;

FIG. 4A is a perspective view illustrating power terminals and an insertion unit of the first exemplary embodiment in a state where the power terminals are not inserted;

FIG. 4B is a perspective view illustrating the power terminals and the insertion unit of the first exemplary embodiment in a state where the power terminals are inserted;

FIG. 5 is a sectional view illustrating a pin receiving member and an insertion pin of the first exemplary embodiment;

FIG. 6A is a plan view illustrating a lever and a contact pin of the first exemplary embodiment in an open posture of the lever;

FIG. 6B is a plan view illustrating the lever and the contact pin of the first exemplary embodiment in a contact posture of the lever;

FIG. 6C is a plan view illustrating the lever and the contact pin of the first exemplary embodiment in a press-fit posture of the lever;

FIG. 7 is a perspective view illustrating a portion of an electronic device of a second exemplary embodiment;

FIG. 8A is a block diagram illustrating a power supply state in the electronic device of the second exemplary embodiment;

FIG. 8B is a block diagram illustrating another power supply state in the electronic device of the second exemplary embodiment;

FIG. 9 is a front view illustrating a power terminal and an insertion unit of a third exemplary embodiment in a state where the power terminal is not inserted;

FIG. 10 is a front view illustrating the power terminal and the insertion unit of the third exemplary embodiment in the state where the power terminal is not inserted;

FIG. 11 is a perspective view illustrating a power terminal and an insertion unit of a fourth exemplary embodiment in a state where the power terminal is not inserted;

FIG. 12 is a plan view illustrating a modified embodiment of a substrate unit; and

FIG. 13 is a plan view illustrating a modified embodiment of the substrate unit.

### DESCRIPTION OF EMBODIMENTS

Hereinafter, a first exemplary embodiment will be described in detail with reference to the drawings.

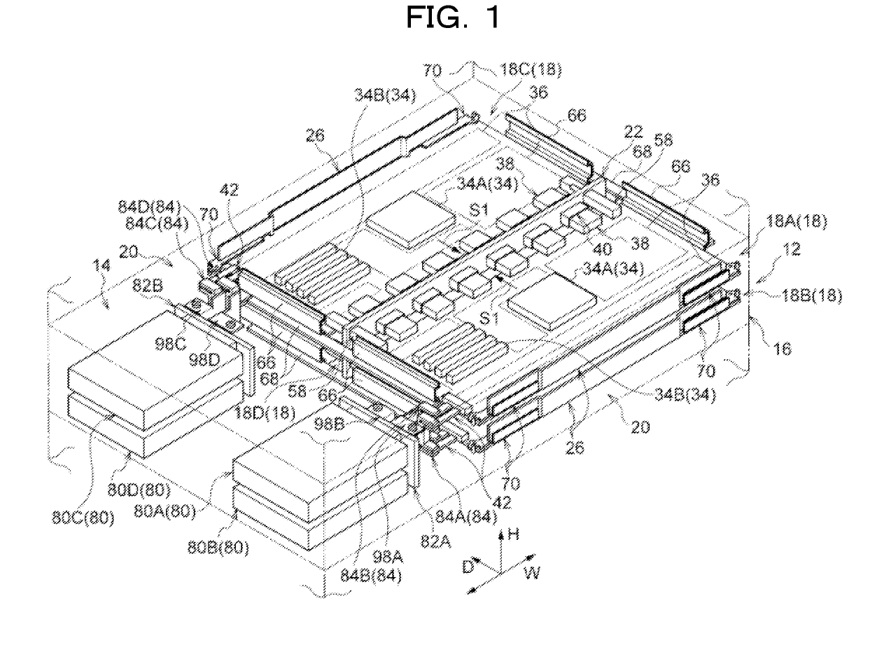

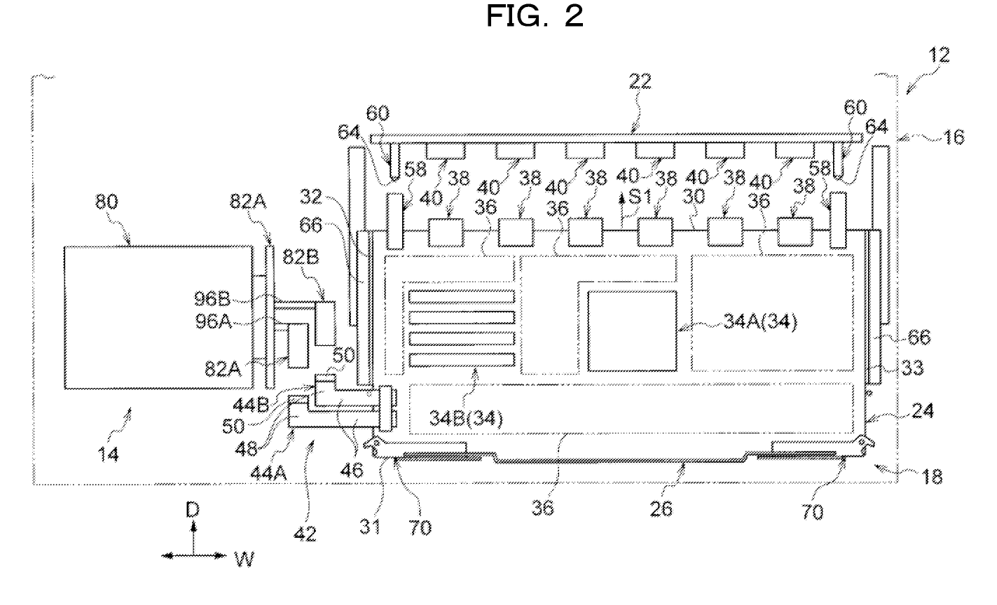

FIG. 1 illustrates an electronic device 12 of the first exemplary embodiment. FIG. 2 illustrates a power supply unit 14 of the electronic device 12, and a substrate unit 18 mounted on a case 16. In the drawings, the depth direction, width direction and height direction of the electronic device 12 are indicated by arrows D, W and H, respectively. These directions are defined merely for the purpose of convenience of description, but do not limit the directions in the actual setting situation of the electronic device 12.

As depicted in FIG. 1, the case 16 is provided with insertion units 20, in which substrate units 18 are inserted in the direction of arrow S1 and accommodated in the insertion unit 20.

A backplane 22 is disposed at a center in the depth direction of the insertion unit 20. Further, two substrate units 18 (a total of four substrates) are disposed at upper and lower positions on a rear side and a front side of the backplane 22, respectively. In order to distinguish the substrate units 18 from each other, the substrate units 18 will be denoted by 18A, 18B, 18C and 18D, respectively.

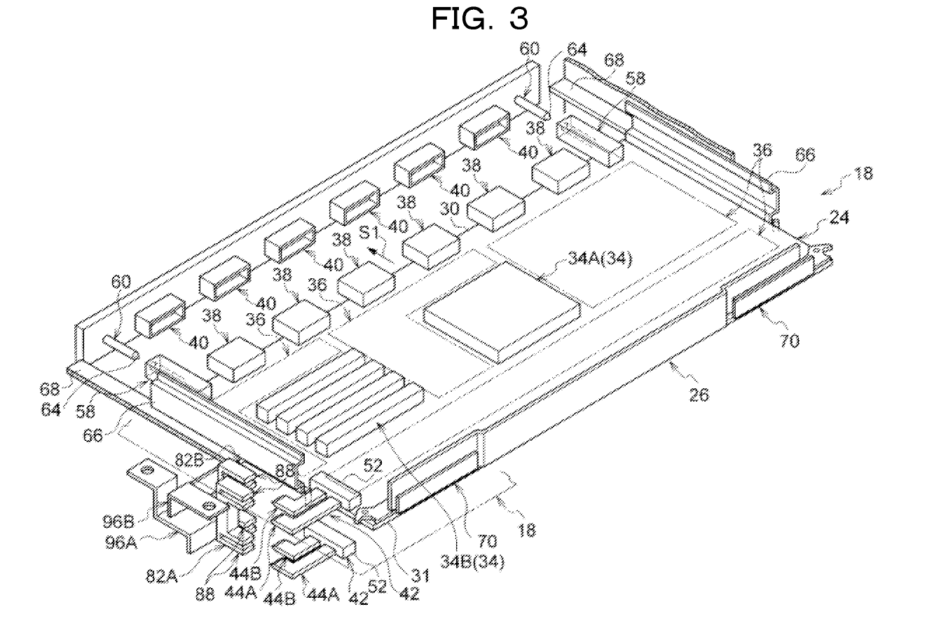

Referring to FIGS. 2 and 3, each substrate unit 18 includes a plate-shaped substrate body 24 formed of an insulative and rigid material, and a support frame 26 configured to support the substrate body 24. In the illustrated example, the substrate body 24 is formed in the shape of a rectangular plate when viewed from the top. FIGS. 2 and 3 illustrate a portion of the support frame 26. The substrate unit 18 is inserted into the insertion unit 20 of the case 16 in the direction indicated by arrow S1 from one edge 30 side of the substrate body 24. Hereinafter, the edge 30 will be referred to as a “first edge 30”.

A plurality of elements 34 are mounted on the substrate body 24. In the illustrated example, integrated circuits 34A and 34B are exemplified as the elements 34. Some portions are also provided as element mounting areas 36 on which various elements may be mounted, even though such integrated circuits 34A and 34B are not mounted thereon. A plurality of elements may also be mounted on the element mounting areas 36. With the substrate unit 18, the plurality of elements 34 may be mounted on the substrate body 24 at high density.

One or more signal terminals 38 are provided on the first edge 30 of the substrate body 24. Further, one or more signal connection members 40 are provided on the backplane 22 to form a one-to-one correspondence with the signal terminal 38. When the substrate unit 18 is inserted to a predetermined position in the insertion unit 20, the signal terminals 38 are connected to the signal connection members 40, so that a signal may be exchanged between the backplane 22 and the substrate unit 18.

Power terminals 42 are provided on an edge 32 (left edge in the example of FIG. 2) adjacent to the first edge 30 of the substrate body 24. Hereinafter, the edge 32 will be referred to as a “second edge 32”.

According to the present exemplary embodiment, the power terminal 42 has two bus bars 44A and 44B for one substrate body 24. Both the bus bars 44A and 44B are formed of a rigid and conductive material (e.g., metal such as copper). In the example illustrated in FIGS. 2 and 3, the bus bars are located on the second edge 32 at a side adjacent to a front side edge 31 (the front side edge when being inserted into the insertion unit 20).

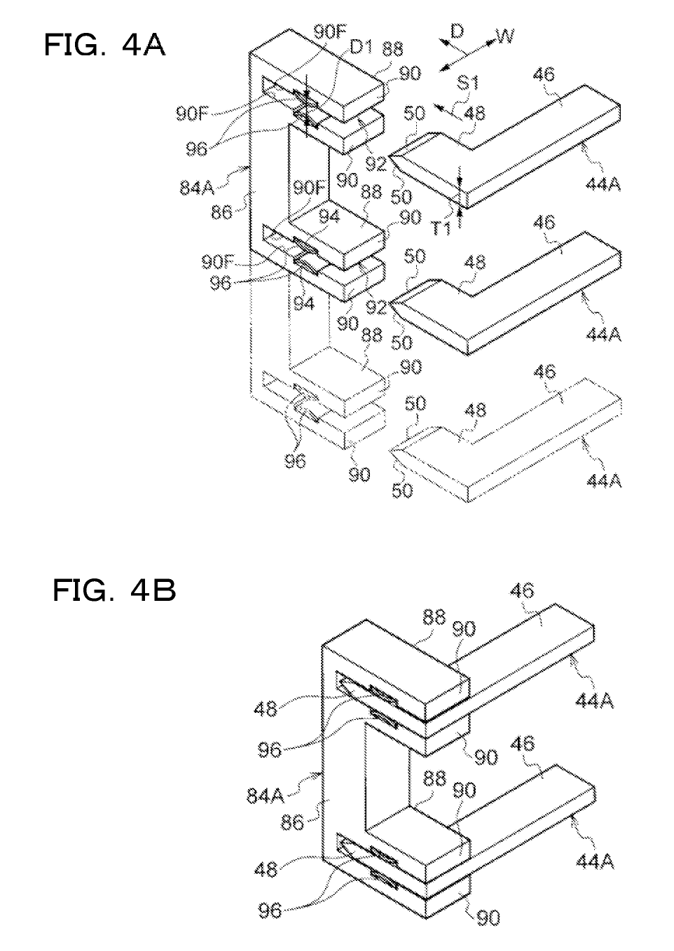

Each of the bus bars 44A and 44B is formed in an approximately L-shaped plate. Specifically, as illustrated in detail in FIG. 4A, each of the bus bars 44A and 44B includes a base end portion 52 secured to the substrate body 24, an extension portion 46 extending in a width direction from the base end portion 52, and a contact portion 48 extending from a front end of the extension portion 46 to the rear side in the insertion direction. Although FIG. 4A illustrates the bus bar 44A, the extension portion 46 and the contact portion 48 are applied to the bus bar 44B in the same manner as the bus bar 44A.

As depicted in FIG. 2, the shapes of the bus bars 44A and 44B are determined such that the width directions of the contact portions 48 thereof are different from each other. Specifically, the extension portion 46 of the bus bar 44B on the rear side in the insertion direction is shorter than the extension portion 46 of the bus bar 44A on the front side in the insertion direction. Therefore, the contact portion 48 of the bus bar 44B is positioned closer to the second edge 32 as compared to the contact portion 48 of the bus bar 44A.

A taper portion 50, of which the thickness is gradually reduced in the insertion direction, is formed on the front end of the contact portion 48.

As depicted in FIG. 3, the bus bars 44A and 44B are provided on one substrate unit 18 to have the same height in the height direction. In the one substrate unit 18, the base end portions 52 of the bus bars 44A, 44B on one substrate unit 18 are fastened to the substrate body 24 by screws. An insulating member 54 is secured to the bus bar 44A, 44B, and serves to secure a predetermined insulating distance between the bus bars 44A and 44B.

One or more pin receiving members 58 are attached to the first side 30 of the substrate body 24. In the illustrated example, two pin receiving members 58 are provided adjacent to both ends in the width direction, respectively. One or more insertion pins 60, which correspond to the pin receiving members 58 one to one, are attached to the backplane 22.

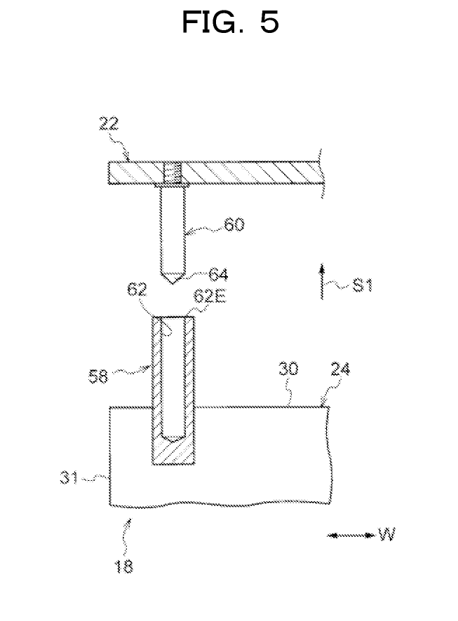

As illustrated in detail in FIG. 5, each pin receiving member 58 is formed in a shape of a block, of which the longitudinal direction corresponds to the insertion direction (the direction indicated by arrow S1) of the substrate unit 18. At the front end side in the insertion direction, insertion holes 62 are formed such that the insertion pins 60 are inserted therein. When the insertion pins 60 are inserted into the insertion holes 62, the substrate unit 18 is positioned in the width direction.

Each of the front ends (the ends of the pin receiving member 58 side) of the insertion pins 60 has a pointed guide surface 64. When the substrate unit 18 moves in the direction illustrated by the arrow S1 and the pin receiving members 58 approaches the insertion pins 60, the positional deviation may occur in the width direction (the direction of arrow W) of the substrate unit 18. This is solved as the guide surfaces 64 come into contact with inner edges 62E of the insertion holes 62 and the substrate unit 18 moves in the width direction.

As illustrated in FIGS. 1 to 3, support plates 66 are attached to two edges (the second edge 32 and an edge 33 opposite to the second edge 32) in the width direction of the substrate body 24. The support plates 66 may be a portion of the support frame 26, and may be formed separately from the support frame 26.

In this regard, rail members 68 are attached to the case 16 in the insertion direction of the substrate unit 18 to be positioned under the support plates 66. When the substrate unit 18 is inserted into the insertion unit 20, the support plates 66 are supported on the rail members 68.

One or more levers 70 are attached to the front edge 31 (the edge opposite to the first edge 30) of the substrate body 24.

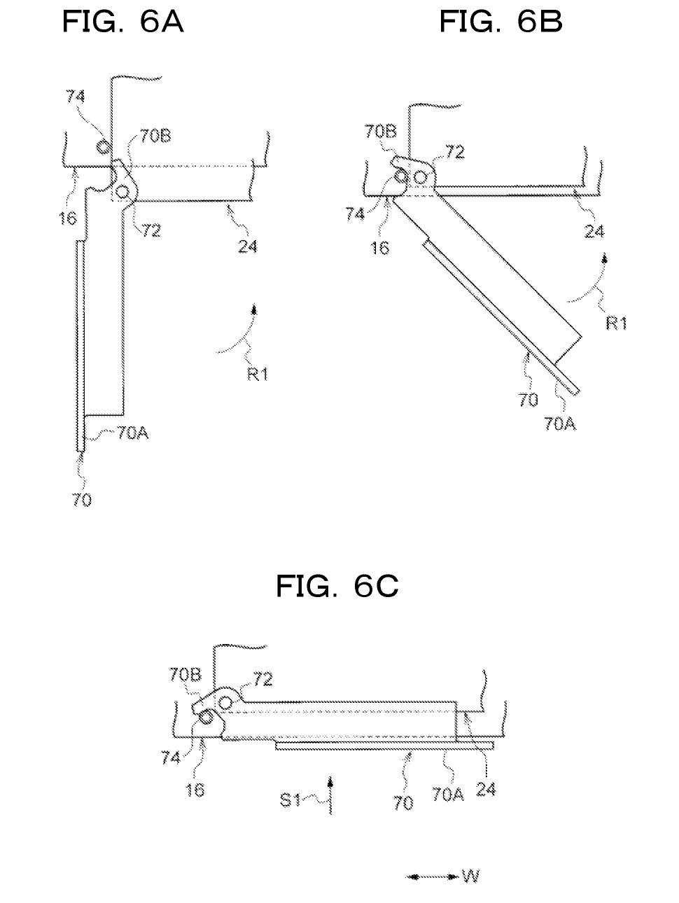

As illustrated in FIGS. 6A to 6C in detail, each lever 70 is rotatable attached to a support shaft 72 that is fixed to the substrate body 24. In the example illustrated in FIG. 6C, an inner portion in the width direction is formed as a manipulation portion 70A that is longer than an outer portion in the width direction than the support shaft 72.

A hook-shaped contact portion 70B is provided at a position opposite to the manipulation portion 70A. In this regard, a contact pin 74 corresponding to the contact portion 70B is fixed to the case 16.

As illustrated in FIG. 6A, when the lever 70 assumes a posture where the manipulation portion 70A is arranged along the insertion direction (hereinafter, referred to as an “open posture”), the lever 70 does not come into contact with the contact pin 74 when the substrate 18 is inserted into the insertion unit 20. Further, when the manipulation portion 70A is rotated in the direction of arrow R1 in a state where the contact portion 70B is located at a deeper position in the insertion direction than the contact pin 74, the contact portion 70B comes into contact with the contact pin 74 from the front end in the insertion direction (hereinafter, referred to as a “contact posture”) as illustrated in FIG. 6B. Further, when the manipulation portion 70A is rotated in the direction of arrow R1, a support-shaft side, that is, the substrate unit 18 moves to a depth side in the insertion direction, using the contact pin 74 as a fulcrum. The support shaft 72, the contact portion 70B, and the contact pin 74 are positioned such that the rotating operation of the lever 70 in the direction of arrow R1 is converted into the inserting operation of the substrate unit 18 (the substrate body 24). The contact pin 74 converts the rotating operation of the lever 70 into the inserting operation of the substrate body 24 while being in contact with the lever 70, and is an example of a bearing portion.

As illustrated in FIG. 6C, in the posture where the manipulation portion 70A is parallel to the first side 30 of the substrate body 24 (hereinafter, referred to as a “press-fit posture”), the signal terminal 38 is connected to the signal connection member 40, and at the same time, the power terminal 42 is connected to a socket 84 (the power supply unit 14).

As illustrated in FIG. 1, a plurality of power supply units 80 are disposed in the case 16 of the electronic device 12 on a side of the insertion unit 20. In the illustrated example, two power supply units are provided on each of the front side and the rear side of the electronic device 12 to overlap each other. Consequently, a total of four power supply units (equal to the number of the substrate units 18) are provided. Hereinafter, in order to distinguish the power supply units 80 from each other, they are referred to as power supply units 80A, 80B, 80C and 80D.

Power supply panels 82A and 82B are attached to the case 16. The power supply panel 82A is shared by the power supply units 80A and 80B, and electrically connected to the power supply units 80A and 80B via a connection member such as a connector. The power supply panel 82B is shared by the power supply units 80C and 80D, and likewise is electrically connected to the power supply units 80C and 80D via a connection member such as a connector.

Further, sockets 84 are provided between the power supply panel 82A and the substrate units 18A and 18B, and between the power supply panel 82B and the substrate units 18C and 18D. In the illustrated example, two sockets are provided on the front side of the case 16 in the depth direction while two sockets are provided on the rear side of the case 16, so that a total of four sockets 84A, 84B, 84C and 84D are provided.

As illustrated in FIGS. 4A and 4B in detail, each socket 84 has a prop 86 that extends in the vertical direction. Power connection members 88 extending to the front side in the insertion direction are provided on the prop 86 in which the number of the power connection members 88 is equal to the number of the substrate units 18 provided in the vertical direction (two in the illustrated example). That is, the socket 84 is configured such that the power connection members 88 are integrally coupled with each other via the prop 86.

Each power connection member 88 has a pair of bearing plates 90 between which a socket recess 92 is opened to the front side of the insertion direction. The power connection member 88 is an example of a power connection member.

Concave receiving portions 94 are formed on opposite surfaces in the pair of bearing plates 90 of the power connection member 88 (inner surfaces 90F of the socket recess 92). Clamping members 96 are formed in a shape of a pair of upper and lower leaf springs made of metal and attached to the concave receiving portions 94, respectively. The clamping members 96 are received in the concave receiving portions 94 in a curved state as a whole such that the rear and front sides in the insertion direction are secured to the bearing plates 90 and the middle portions in the insertion direction are spaced apart from the bearing plate 90, respectively.

At a portion where a space between the clamping members 96 is the narrowest, the space has a size D1 which is smaller than the thickness T1 of each of the bus bars 44A, 44B. When the contact portion 48 of the bus bar 44A or 44B is inserted between the clamping members 96, the clamping members 96 are elastically deformed to sandwich and to be in close contact with the contact portion 48 from the top and bottom sides.

The sockets 84A, 84B are disposed to be misaligned in the depth and width directions so that the clamping members 96 come into contact with the contact portions 48 of the bus bars 44A, 44B in a state where the substrate units 18A, 18B on the front side are inserted into the insertion unit 20. Likewise, the sockets 84C, 84D are disposed to be misaligned in the depth and width directions so that the clamping members 96 come into contact with the contact portions 48 of the bus bars 44A, 44B in a state where the substrate units 18C, 18D on the rear side are inserted into the insertion unit 20.

As illustrated in FIG. 1, the clamping members 96 of the socket 84A are supplied with power from the power supply panel 82A through a power supply bar 98A, and have a relatively high potential (e.g., 12 volts). In contrast, the clamping members 96 of the socket 84B are supplied with power from the power supply panel 82A through a power supply bar 98B, and have a relatively low potential (e.g., 0 volt).

The clamping members 96 of the socket 84C are supplied with power from the power supply panel 82B through a power supply bar 98C, and have a relatively high potential (e.g., 12 volts). In contrast, the clamping members 96 of the socket 84D are supplied with power from the power supply panel 82B through a power supply bar 98D, and have a relatively low potential (e.g., 0 volt).

When the bus bars 44 are electrically connected to the clamping members 96 in the state where a potential difference occurs between the clamping members 96 in the sockets 84A, 84B and a potential difference occurs between the clamping members 96 in the sockets 84C, 84D, power is supplied to the substrate units 18.

According to the present exemplary embodiment, since two substrate units 18 are configured to be disposed in the height direction, each socket 84 is also provided with two power connection members 88. However, the number of the power connection members 88 provided for each socket 84 may be increased in conformity with the number of the substrate units 18 in the height direction. For example, as illustrated by two-dot chain lines in FIG. 4A, the prop 86 may be lengthened and a new power connection member 88 may be provided on the lengthened portion of the prop 86.

Next, an action of the present exemplary embodiment will be described.

As depicted in FIGS. 2 and 3, in the substrate unit 18 of the present exemplary embodiment, the signal terminals 38 are installed on the first edge 30 of the substrate body 24, and the power terminal 42 is installed on the second edge 32. Thus, as compared to a structure in which both the signal terminals 38 and the power terminal 42 are installed on the first edge 30, the interval of the signal terminals 38 may be increased such that high-densification may be avoided.

Since the wiring density of the signal wirings connected to the signal terminals 38 may be reduced in the substrate body 24, the generation of noise may be suppressed. In a case where the density of the signal wirings is increased for the purpose of high-speed transmission, when the signal wirings are thinned, the electric resistance of the wirings may increase and thus, the heat generation amount may become larger. However, the present exemplary embodiment may suppress the heat generation amount in the signal wirings by suppressing the thinning of the signal wirings.

In order to avoid the high-densification of the signal wirings, adopting configuration in which the first edge 30 is lengthened so as to increase the interval of the signal terminals 38 may be considered but may cause the widening of the substrate unit. Since the present exemplary embodiment does not adopt the configuration in which the first side 30 is lengthened, the miniaturization of the substrate unit 18 may be attained.

In addition, the substrate unit 18 is supplied with power by the power terminal 42 on the second edge 32 that is different from the first edge 30 equipped with the signal terminals 38. Thus, the length of the wirings between the power terminals and the elements 34 located near to the power terminal 42 may be reduced to suppress the voltage drop. For example, when an element consuming large power is located near to the power terminal 42, the voltage drop of the power supplied to the element may be suppressed.

Since the substrate unit 18 is supplied with power from the second edge 32, the power supply unit 14 is not mounted on the backplane 22 side in the case 16 of the electronic device 12. Further, it is unnecessary to install power supply wiring or a connector for a power source at the backplane 22. Therefore, miniaturization and weight reduction of the backplane 22 and cost reduction may be attained.

When the substrate unit 18 is inserted into the insertion unit 20 from the first edge 30 side, the signal terminals 38 are electrically connected to the signal connection members 40. At this time, the power terminal 42 is also connected to the socket 84 (the power supply unit 14). That is, when the insertion of the substrate unit 18 into the insertion unit 20 is done, both the signal terminal 38 and the power terminal 42 may be connected. Thus, the connecting operation may be facilitated during the assembly or repair. For example, since the power terminal 42 is not connected with the socket 84 using, for example, a screw in a manufacturing site of the electronic device 12, assembling operation may be facilitated. For example, when the electronic device 12 is repaired or inspected, the substrate unit 18 to be replaced or added may be replaced or added without stopping the operation of other members than the substrate unit 18 that is to be replaced or extended.

In practice, in order to insert the substrate unit 18 into the insertion unit 20 such that the former is accommodated in the latter, the lever 70 assumes the open posture as illustrated in FIG. 6A and the substrate unit 18 is placed such that the support plates 66 are supported by the rail members 68 in a state where the first edge 30 side is positioned to face the backplane 22. Then, the substrate unit 18 is moved in the direction of arrow 51. The support plates 66 are supported by the rail members 68, and the substrate unit 18 is moved in the direction of arrow 51 while being guided as a whole by the rail members 68.

During the movement, the insertion pins 60 are inserted into the insertion holes 62 in the pin receiving members 58. The guide surfaces 64 are formed on the front ends of the insertion pins 60 and, when there is a widthwise deviation of the substrate unit 18, the guide surfaces 64 come into contact with the inner edges of the insertion holes 62 when the insertion pins 60 are inserted into the insertion holes 62. As a result, the substrate unit 18 is moved in the width direction, and the widthwise deviation may be eliminated.

Since the lever 70 assumes the open posture, it does not come into contact with the contact pin 74. In the state where the contact portion 70B is located at the rear side in the insertion direction as compared to the contact pin 74, the manipulation portion 70A is rotated in the direction indicated by arrow R1 in FIG. 6A. As a result, the lever 70 assumes the contact posture, so that the contact portion 70B comes into contact with the contact pin 74 starting from the front end side in the insertion direction, as illustrated in FIG. 6B.

In addition, when the manipulation portion 70A is rotated in the direction indicated by arrow R1, the rotation is converted into the movement of the substrate unit 18 in the insertion direction, and the substrate unit 18 is moved to the rear side in the insertion direction. That is, since the rotating operation of the lever 70 is converted into the inserting operation of the substrate unit 18 (the substrate body 24), the insertion work may be facilitated.

Then, as illustrated in FIG. 6C, in the state where the lever 70 is in the press-fit posture, the substrate unit 18 is press-fitted to the rear side in the insertion direction. At this time, the signal terminals 38 are connected to the signal connection members 40. When the bus bars 44A and 44B are respectively inserted into the corresponding socket recesses 92 to come into contact with the clamping members 96, the power terminal 42 is connected to the sockets 84 (the power supply unit 14). That is, when the substrate unit 18 is press-fitted into the rear side by rotating the lever 70, the signal terminals 38 and the power terminal 42 may be connected to the signal connection members 40 and the socket 84, respectively. As a result, the connecting work may also be facilitated.

In the two bus bars 44A and 44B of the power terminal 42, the contact portions 48 are located at different positions in the width direction. Thus, the substrate unit 18 may be accommodated in the insertion unit 20 while avoiding inadvertent interference of the contact portions 48. Since the bus bars 44A and 44B are not arranged in the vertical direction so as to avoid the interference of the contact portions 48, the height of the substrate unit 18 may be reduced.

Since the taper portions 50 are formed on the bus bars 44A and 44B, the insertion of the bus bars between the clamping members 96 may be facilitated. Particularly, when the substrate unit 18 is inserted into the insertion unit 20, it is difficult to directly push the bus bars 44A and 44B. Even though it is difficult to directly push the bus bars 44A and 44B, it possible to insert the bus bars 44A and 44B between the clamping members 96 without directly pushing the bus bars 44A and 44B since the taper portions 50 are formed.

When the bus bar 44A is inserted between the clamping members 96, the clamping members 96 are elastically deformed such that the space therebetween is expanded. The clamping members 96 sandwich the bus bar 44A therebetween by an elastic reactive force. Therefore, the contact state between the bus bar 44A and the clamping members 96, i.e., the electrically connected state may be surely maintained.

Next, a second exemplary embodiment will be described. The components and members of the second exemplary embodiment which are the same as those of the first exemplary embodiments will be denoted by the reference numerals which are the same as those of the first exemplary embodiment, and the detailed descriptions thereof will be omitted.

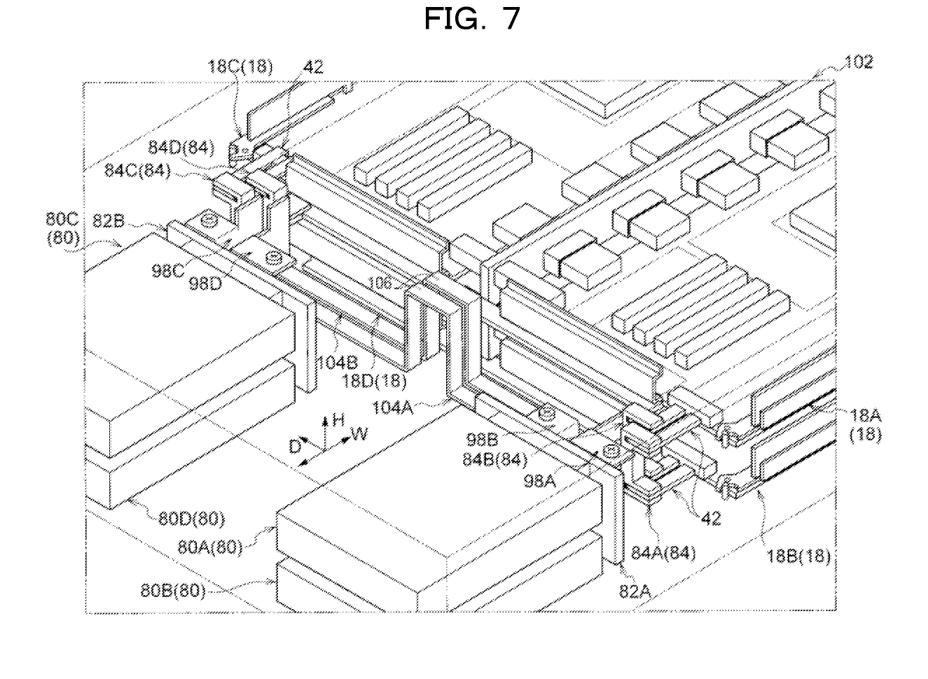

FIG. 7 illustrates a portion of an electronic device 102 according to the second exemplary embodiment in an enlarged scale. In the second exemplary embodiment, a front side power supply bar 98A and a rear side power supply bar 98C, i.e power supply bars having relatively high potentials are electrically connected to each other via a connecting bar 104A.

Likewise, a front side power supply bar 98B and a rear side power supply bar 98D, i.e, power supply bars having relatively low potentials are electrically connected to each other via a connecting bar 104B.

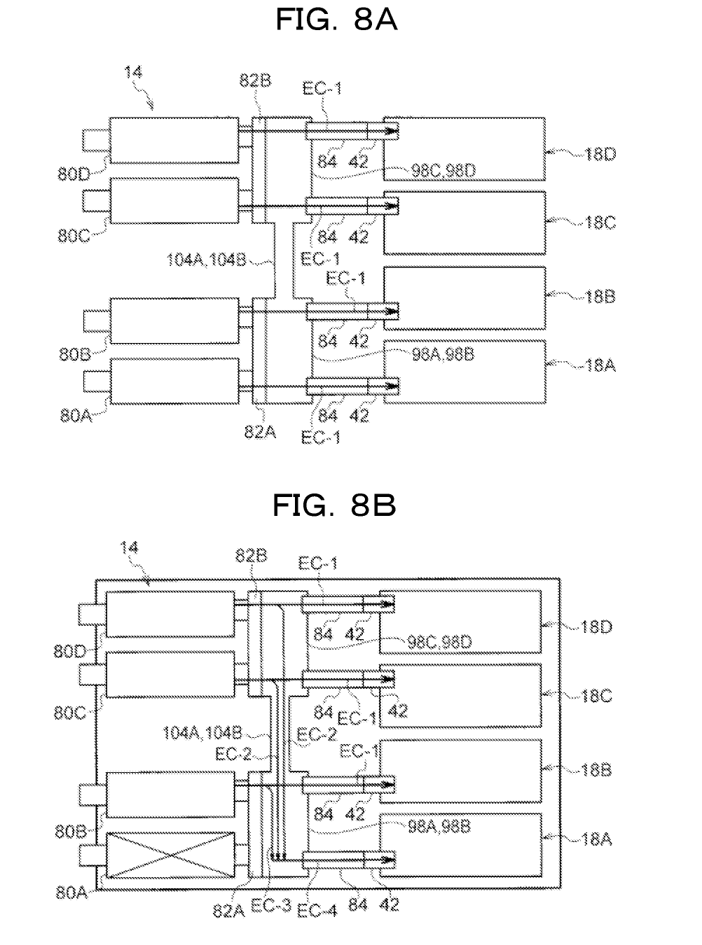

Thus, as illustrated in FIGS. 8A and 8B, according to the second exemplary embodiment, power may be exchanged between two sockets 84A and 84B on the front side in the depth direction and two sockets 84C and 84D on the rear side in the depth direction via the connecting bars 104A and 104B, respectively. For example, even if power supply from one of the four power supply units 80 is cut off, the reduced power portion may be supplemented by increasing the amount of power supplied from the remaining three power supply units 80.

FIG. 8A is a block diagram illustrating the case in which all of the four power supply units 80A, 80B, 80C and 80D supply power. In this case, power supplied from each of the power supply units 80A, 80B, 80C and 80D is, for example, 100 A at 12 volts. Here, as an example, a case in which the power supply units 80A, 80B, 80C and 80D supply power to the corresponding substrate units 18A, 18B, 18C and 18D is exemplified (see arrows EC-1). However, a case in which a current flowing in the connecting bars 104A and 104B is generated is not excluded.

In contrast, FIG. 8B is a block diagram illustrating the case in which the power supply unit 80A stops supplying power and the remaining three power supply units 80B, 80C and 80D supply power.

In this example, it is assumed that the power supplied from the power supply units 80B, 80C and 80D is 133A at 12 volts. That is, each of the three power supply unit 80B, 80C and 80D supplies extra power of 33 amperes, in addition to the supply of power (see arrows EC-1) to the corresponding substrate units 18B, 18C and 18D.

Further, the substrate unit 18A is supplied with power (about 66 amperes in total) from the power supply units 80C and 80D through the connecting bars 104A and 104B to (see arrows EC-2). The substrate unit 18A is also supplied with power (33 amperes) from the power supply unit 80B (see arrow EC-3). Thus, by a current of nearly 100 amperes in total, power may be supplied to the substrate unit 18A (see arrow EC-4).

In the foregoing, although the case in which the power supply unit 80A stops supplying power has been exemplified, even if the power supplied from another power supply unit 80 is lowered, the shortage of power may be supplemented using the power supply units 80 that do not stop supplying power.

The above-mentioned voltage and current values are only an example.

In the second exemplary embodiment, in the example illustrated in FIG. 7, an upwardly convex portion 106 is formed on a central portion of each of the connecting bars 104A and 104B. However, the convex portion 106 may not be formed and the connecting bars 104A and 104B may have a flat shape. When the convex portion 106 is formed, various members of the electronic device 102 may be disposed in the inside the convex portion 106 (it is concave when viewed from the bottom side).

The connecting bars 104A and 104B may be manufactured as separate members on the front and rear sides in the insertion direction, and connected to each other via a connecting members such as screws or rivets.

Next, third and fourth exemplary embodiments will be described. Since the overall configurations of the electronic device and the substrate unit in the third and fourth exemplary embodiments may be applied to be the same as those of the first or second exemplary embodiment, the descriptions thereof will be omitted. Further, the components and members in the third and fourth exemplary embodiments which are the same as those in the first exemplary embodiment will be denoted by the reference numerals which are the same as those in the first exemplary embodiment, and the detailed descriptions thereof will be omitted.

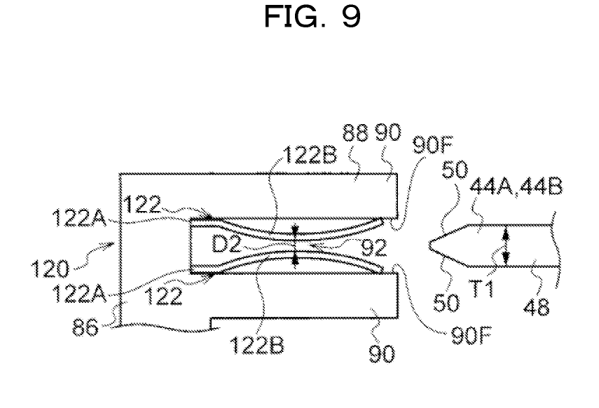

FIG. 9 is illustrates a portion of a socket 120 of the third exemplary embodiment in an enlarged scale. A pair of clamping members 122, each of which has a flat portion 122A and a curved portion 122B, are disposed in the power connection terminal 88 of the socket 120 of the third exemplary embodiment. The clamping members 122 are secured to the opposite surfaces 90F by bonding or the like in a direction where the flat portions 122A are located at the deeper side of the power connection member 88. The curved portions 122B of the clamping members 122 are spaced apart from the bearing plates 90. The narrowest space portion between the clamping members 122 is formed to have an interval D2 that is less than a thickness T1 of the bus bars 44A and 44B.

In the third exemplary embodiment, when the contact portion 48 of the bus bar 44A or 44B is inserted between the clamping members 122, the clamping members 122 are elastically deformed and sandwich the contact portion 48 in the top and bottoms sides for a close contact.

In the socket 120 of the third exemplary embodiment, the concave receiving portions 94 (see FIG. 4A) may not be formed on the opposite surfaces 90F (the inner surfaces 90F of the socket recess 92) in the pair of bearing plates 90 of the power connection member 88.

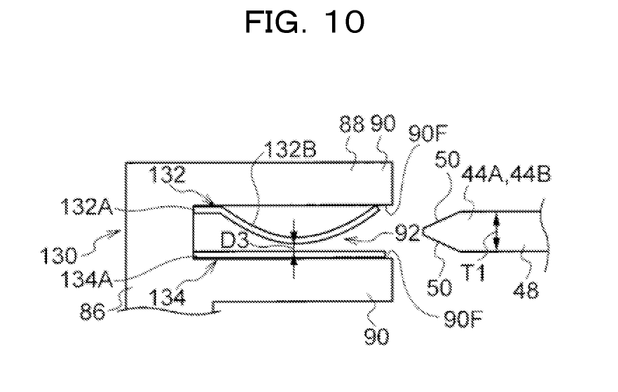

FIG. 10 illustrates a part of a socket 130 of the fourth exemplary embodiment. In the power connection member 88 of the socket 130 of the fourth exemplary embodiment, one clamping member 132 having a flat portion 132A and a curved portion 132B, and one clamping member 134 having a flat portion 134A are disposed to face each other.

The clamping members 132 are secured to the opposite surface 90F by bonding or the like in a direction where the flat portion 132A is located at the deeper side of the power connection member 88. The clamping member 134 is secured to one of the opposite surfaces 90F by, for example, bonding to be in surface contact with the opposite surface 90F. The narrowest space portion between the clamping members 132 and 134 is formed to have an interval D3 that is less than a thickness T1 of the bus bar 44A or 44B.

In the fourth exemplary embodiment, when the contact portion 48 of the bus bar 44A or 44B is inserted between the clamping members 132 and 134, the clamping member 132 is elastically deformed. Further, the contact portion 48 is sandwiched by and closely contacted with the clamping members in the top and bottom sides thereof.

In the socket 130 of the fourth exemplary embodiment, the concave receiving portions 94 (see FIG. 4A) may not be formed on the opposite surfaces 90F (the inner surfaces 90F of the socket recess 92) in the pair of bearing plates 90 of the power connection member 88.

As described above, the bus bar 44A or 44B is also sandwiched in the thickness direction by the clamping members as in the first exemplary embodiment. When the bus bar 44A or 44B is sandwiched by the clamping members as described above, the electric connection between the bus bar 44A, 44B and the clamping members may be stably maintained.

In the third and fourth exemplary embodiments, since the concave receiving portions 94 are not formed on the opposite surfaces 90F of the bearing plate 90, the structure may be simplified. Meanwhile, in the configuration illustrated in FIG. 4A, since the concave receiving portions 94 are formed on the opposite surfaces 90F of the bearing plate 90, the deviation of the clamping members 96 from the opposite surfaces 90F may be suppressed.

In the fourth exemplary embodiment, one clamping member 134 may be easily formed since the clamping member 134 has a flat shape. Further, since the contact portion 48 of the bus bar 44A or 44B comes into contact with the flat portion 134A of the clamping member 134 having the flat shape, the contact area of the clamping member 134 is larger than that of the curved clamping member 132.

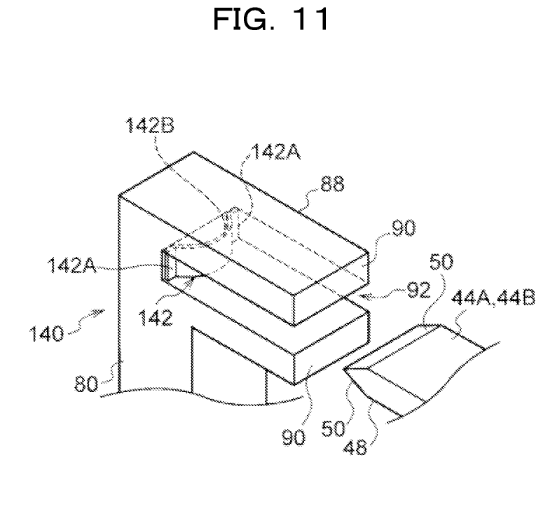

FIG. 11 illustrates a socket 140 of a fifth exemplary embodiment. One contact member 142 is disposed in the power connection member 88 of the socket 140 of the fifth exemplary embodiment. The contact member 142 has flat portions 142A on both ends thereof and a curved portion 142B on a central portion, and the flat portions 142A are attached to a surface of the deeper side of the power connection member 88 by an adhesive. The curved portion 142B is curved towards the front side of the power connection member 88.

In the fifth exemplary embodiment, when the bus bar 44A, 44B is inserted to the depth of the power connection member 88, the front end of the bus bar 44A or 44B comes into contact with the contact member 142.

In any one of the third, fourth and fifth exemplary embodiments, since the concave receiving portions 94 (see FIG. 4A) are not formed on the bearing plates 90, the structure may be simplified.

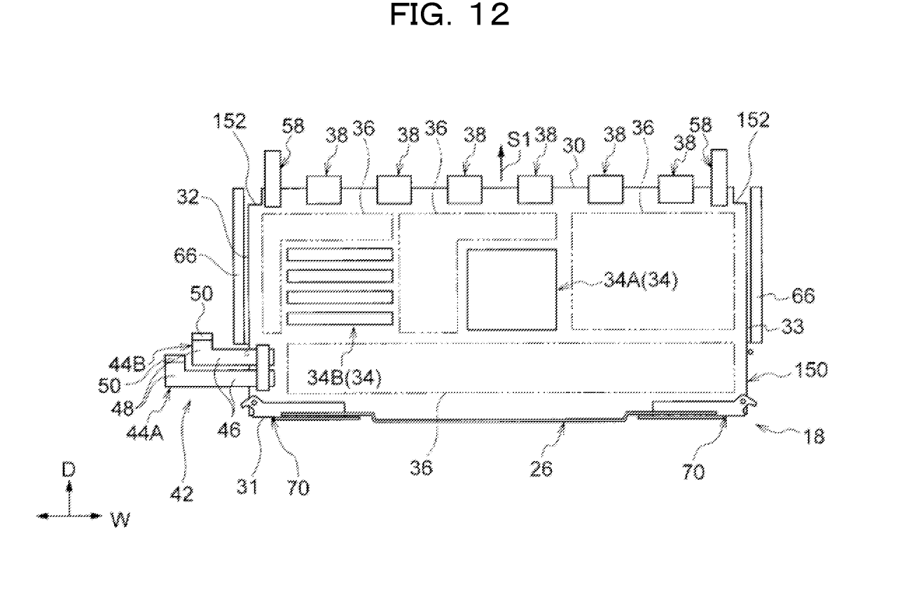

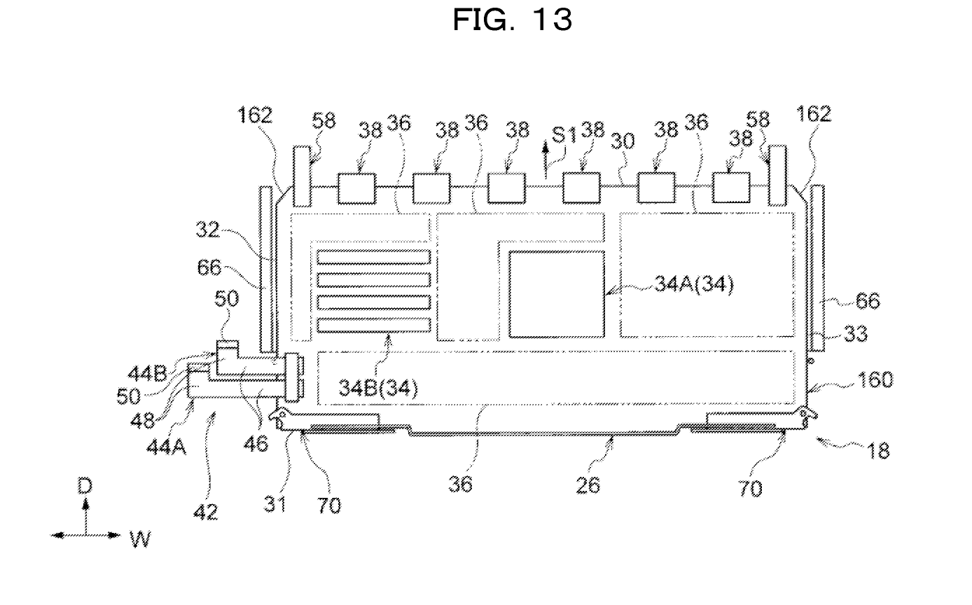

When viewed from the top, the illustrated substrate body 24 is formed in a rectangular shape, and the first edge 30 is adjacent to the second edge 32. However, the edge equipped with the signal terminals 38 is not necessarily adjacent to the edge equipped with the power terminal 42. For example, the power terminal 42 may be installed at the edge 33 opposite to the edge 32. As illustrated in FIG. 12, a substrate body 150 may have a notch 152 between the first and second edges 30 and 32. Alternatively, as illustrated in FIG. 13, a substrate body 160 may have an inclined edge 162 between the first and second edges 30 and 32.

In the substrate body having the notch 152 or the inclined side 162 between the first and second edges 30 and 32, the first edge 30 is not adjacent to the second edge 32. However, even in the substrate body having the notch 152 or the inclined side 162 as described above, the signal terminals 38 may be equipped on the first edge 30 and the power terminal 42 may be equipped on the second edge 32. In the configuration where the first edge 30 is adjacent to the second side 32, the substrate body 24 may adopt a more versatile shape such as the above-mentioned rectangular shape.

When viewing the substrate body 24 from the top, the first edge 30 is not necessarily perpendicular to the second edge 32. It is possible to use the substrate body configured such that the first and second edges 30 and 32 form an acute or obtuse angle.

In the above example, the electronic device 12 is configured such that a plurality of substrate units 18 are laid in parallel to each other in the thickness direction and accommodated in the case 16. However, the electronic device 12 may be configured to accommodate one substrate unit in the thickness direction. When the plurality of substrate units 18 are accommodated in the case 16 in parallel to each other in the thickness direction, the space within the case 16 may be efficiently used. In such a configuration in which the plurality of substrate units 18 are laid in parallel to each other in the thickness direction, the high-densification of the signal wirings on the substrate body 24 of each substrate unit 18 may be avoided and the bus bars 44 may be connected to the sockets 84 by inserting the substrate units 18 into the insertion unit 20.

In the foregoing, although the socket 84 has been exemplified as an example of power connection member, any other member is acceptable as long as the bus bar 44 is electrically connected to the member when the substrate unit 18 is inserted into the insertion unit 20. For example, a simple metal plate or metal rod may be used.

The power terminal is not limited to the bus bar 44 as described above, but any other member is acceptable as long as it is electrically connected to the power connection member when the substrate unit 18 is inserted into the insertion unit 20. For example, a simple metal rod may be acceptable or a member formed by lengthening a portion of the substrate body 24 and forming a metal film on a surface of the lengthened portion may also be acceptable.

The electronic device 12 of each exemplary embodiment may be a server or large-scale computer without being limited to a particular device. Further, the electronic device is not limited to a data processor, but may be, for example, a power supply device that stably supplies power to any other external device. The power supply device is provided with a substrate unit, on which elements including a transformer, a capacitor, and an inverter are mounted within the case.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the exemplary embodiments of the present invention have been described in detail, it should be understood that the various changes, substitutions, and alterations could be made hereto without departing from the spirit and scope of the invention.

What is claimed is:

1. An electronic device comprising:
a substrate unit including a signal terminal provided over a first edge of a substrate body, and a power terminal provided over a second edge that is different from the first edge; and
a case including an insertion unit into which the substrate unit is inserted from the first edge, a signal connection member to which the signal terminal is coupled when the substrate unit is inserted into the insertion unit, and a power connection member to which the power terminal is coupled when the substrate unit is inserted into the insertion unit.

2. The electronic device according to claim 1, wherein the power connection member includes a clamping member configured to sandwich the power terminal to be electrically coupled thereto.

3. The electronic device according to claim 2, wherein the clamping member elastically sandwiches the power terminal.

4. The electronic device according to claim 1, wherein the power terminal includes a taper portion, of which the thickness is gradually reduced toward an insertion direction.

5. The electronic device according to claim 1, wherein a plurality of power terminals are provided over the substrate unit, and
contact portions of the plurality of power terminals are located at different positions in a width direction which is orthogonal to the insertion direction.

6. The electronic device according to claim 1, wherein the first edge and the second edge are adjacent to each other.

7. The electronic device according to claim 1, further comprising:
a lever rotatable provided over the substrate body; and
a bearing portion provided in the case and coming into contact with the lever so as to convert a rotating operation of the lever into an inserting operation of the substrate body.

8. The electronic device according to claim 1, wherein the insertion unit is configured such that a plurality of substrate units are inserted therein in parallel to each other in a thickness direction, and
a plurality of power connection members are arranged along the arranged direction of the plurality of substrate units.

9. A substrate unit comprising:
a substrate body;
a signal terminal provided over a first edge of the substrate body; and
a power terminal provided over a second edge that is different from the first side of the substrate body.

10. The substrate unit according to claim 9, wherein the power terminal comprises a taper portion, of which the thickness is gradually reduced towards the first edge.

11. The substrate unit according to claim 9, wherein a plurality of power terminals are provided, and
contact portions of the power terminals are located at different positions in a direction along the first edge.

12. The substrate unit according to claim 9, wherein the first edge is adjacent to the second edge.
